(19) United States
(12) Patent Application Publication
(10) Pub. No.: US 2015/0292113 A1
(43) Pub. Date: Oct. 15, 2015

(54) METAL SINGLE CRYSTAL IN WHICH METAL ELEMENT IS SUBSTITUTED

(71) Applicant: BUSAN NATIONAL UNIVERSITY INDUSTRIAL UNIVERSITY COOPERATION FOUNDATION, Busan (KR)

(72) Inventors: Se-young Jeong, Busan (KR); Ji-young Kim, Yangsan-si Gyeongsangnam-do (KR); Yong-chan Cho, Busan (KR); Sang-eon Park, Busan (KR); Chae-ryong Cho, Busan (KR)

(21) Appl. No.: 14/430,312

(22) PCT Filed: Sep. 17, 2013
(86) PCT No.: PCT/KR2013/008381

§ 371 Date: Jun. 19, 2015

(30) Foreign Application Priority Data
Sep. 21, 2012 (KR) 10-2012-0105133

(51) Int. Cl. C30B 29/52; C30B 29/02; C22C 5/08; C30B 15/00

(52) U.S. Cl. CPC C30B 29/52; C30B 15/00; C30B 29/02; C22C 5/08

(57) ABSTRACT

The present invention relates to a metal single crystal in which a metal element is substituted, wherein a metal element A is doped with a metal element B different from the metal element A to form A_{1-X}B_{X}, and a mixed single crystal is formed therefrom by high temperature melting (wherein the metal element A is any one of silver, copper, platinum and gold; the metal element B is any one of silver, copper, platinum and gold; and 0.01≦x≦0.09). Therefore, a metal single crystal, which is a mixed crystal with more superior electrical properties than a conventional metal, is formed by doping a metal with excellent electrical properties with a metal element different from the metal, and growing the doped metal into a mixed crystal.

### FIELD OF THE INVENTION

The present invention relates to a metal single crystal with a substituted hetero-metal atom. More particularly, the present invention relates to a hetero-metal atom-substituted metal single crystal that grows as a mixed crystal that is formed by doping a base metal with a hetero metal atom and which exhibits better electrical properties than the base metal.

### BACKGROUND OF THE INVENTION

Generally, a metal has good electrical and thermal conductivity. Particularly, silver and copper have long been extensively studied thanks to their superior electroconductivity to that of other metals, and thus find applications in various industries. Good as they are in electric properties, pure metals have limitations for use in applied fields due to metals in pure form being too soft. To solve this problem, metal alloys have been developed.

However, metal alloys tend to lose the excellent electrical properties of pure metals when processed for obtaining strength.

There exist materials that should be improved in electrical properties. For materials adapted to create strong magnetic fields, such as bitter magnets, for example, attempts have been made to improve their poor electrical properties by controlling purity or to improve both electrical and mechanical properties by cold working.

Further, methods for growing mixed crystals have been introduced so as to improve physicochemical properties of materials. Korean Unexamined Patent Application Publication No. 10-1990-0012851 discloses a “Growth Method of Mixed Crystal”.

This conventional technique is a method for growing, as a melt of an oxidative multicomponent system, a mixed crystal having at least two lattice sites that are different in the number of adjacent oxygen ions from each other, wherein a uniform crystal grows in such a manner that cations are selected to occupy a first lattice site having the largest number of adjacent oxygen ions and then a second lattice site having the next largest number of adjacent oxygen ions, the selection being made so that the bond length ration between the cations at the first lattice site and at the second lattice site ranges from 0.7 to 1.5.

Another technique is found in Korean Unexamined Patent Application Publication No. 10-2005-0030601, titled “Crystal production method for gallium oxide-iron mixed crystal”.

This conventional technique is a manufacturing method of a gallium iron oxide mixed crystal. Ga₂₋ₓFeₓO₃ a single crystal having an orthorhombic crystal structure is formed by a floating zone melting method in which ends of material bars, which are disposed at an upper and a lower position and which are composed of Ga₂₋ₓFeₓO₃, are heated in a gas atmosphere with thermal sources disposed at confocal areas so as to form a floating melting zone between the ends of the material bars that are disposed at the upper and the lower position and which are composed of Ga₂₋ₓFeₓO₃.

Another technique is also found in Korean Unexamined Patent Application Publication No. 10-2010-0119782, titled “Composite Compound with Mixed Crystalline Structure”.

This conventional technique concerns a mixed crystal compound with the general formula LiₐA_{1-y}B_{y}(XO₄)_{b}/M_{c}N_{d} (wherein: A is a first-row transition metal including Fe, Mn, Ni, V, Co and Ti; B is a metal selected from the group Fe, Mn, Ni, V, Co, Ti, Mg, Ca, Cu, Nb, Zr and rare-earth metals; X is selected from elements P, Si, S, V and Ge; M is metal selected from groups IA, NA, IMA, IVA, VA, IMB, IVB and VB of the periodic table; N is selected from among O, N, H, S, SO₄, PO₄, OH, Cl, and F; and 0<a≦1, 0≦y≦0.5, 0<b≦1, 0<c≦4 and 0<d≦6). The composite lithium compound having a mixed crystalline structure can be used as a cathode material for lithium secondary batteries.

However, the conventional techniques are directed to oxide or composite compounds with multicomponents, in which nowhere are attempts being made to improve electrical properties by growing heteroatom-doped metal atoms into a mixed metal single crystal.

### SUMMARY OF THE INVENTION

Accordingly, the present invention has been made keeping in mind the above problems occurring in the prior art, and an object of the present invention is to provide a hetero-metal atom-substituted metal single crystal that is formed by growing a base metal doped with a hetero metal atom as a mixed crystal and which exhibits better electrical properties than the base metal.

In order to accomplish the above object, an aspect of the present invention provides a hetero-metal atom-substituted metal single crystal, formed by doping metal element A with a hetero metal atom B to form an A_{1-X}B_{X} material wherein metal A is an element selected from among silver, copper, platinum, and gold, B is an element selected from among silver, copper, platinum and gold, the metal B being different from the metal A, and 0.01≦x≦0.09, and growing the material as a mixed crystal by means of a high temperature melting method.

In one preferred embodiment of the present invention, the metal A is silver and the metal B is copper.

In another preferred embodiment of the present invention, the high-temperature melting process is a Czochralski process.

Therefore, a metal single crystal can be obtained by growing a base metal doped with a hetero metal element into a mixed crystal that is superior in electrical properties to the base metal.

Accordingly, a metal single crystal, which is a mixed crystal with superior electrical properties to a conventional metal, is formed by doping a metal with excellent electrical properties with a metal element different from the metal, and growing the doped metal into a mixed crystal.

Grown from an electrically superior metal doped with a hetero-metal element, the mixed crystal as a metal single crystal, in accordance with the present invention as described above, exhibits better electrical properties than the original metal and is improved in strength.

### BRIEF DESCRIPTION OF THE DRAWINGS

FIG. 1 shows electrical resistivity according to scattering between electrons and lattices.

FIG. 2 shows an image of the metal single crystal formed in Example 2, together with diagrams for structurally analyzing the metal single crystal.

FIG. 3 is a graph of the electrical resistivity of the metal single crystals in Examples and Comparative Example of the following Example section.

### DETAILED DESCRIPTION OF THE INVENTION

Below, a detailed description will be given of the present invention with reference to the accompanying drawings.

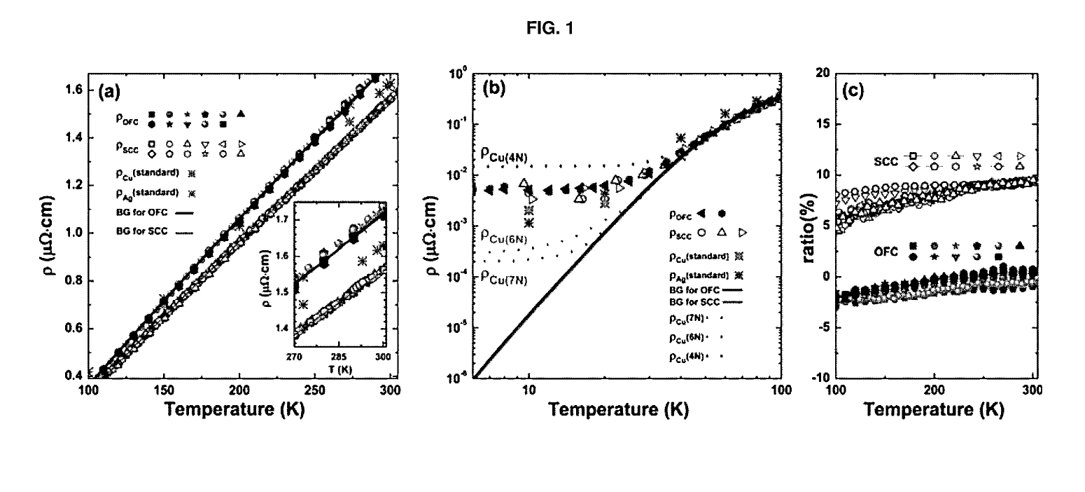

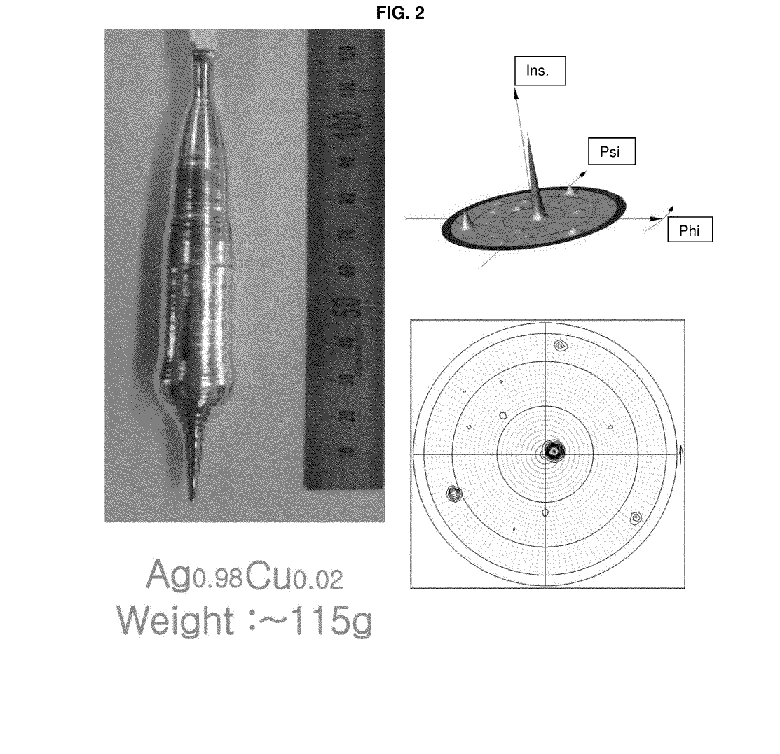

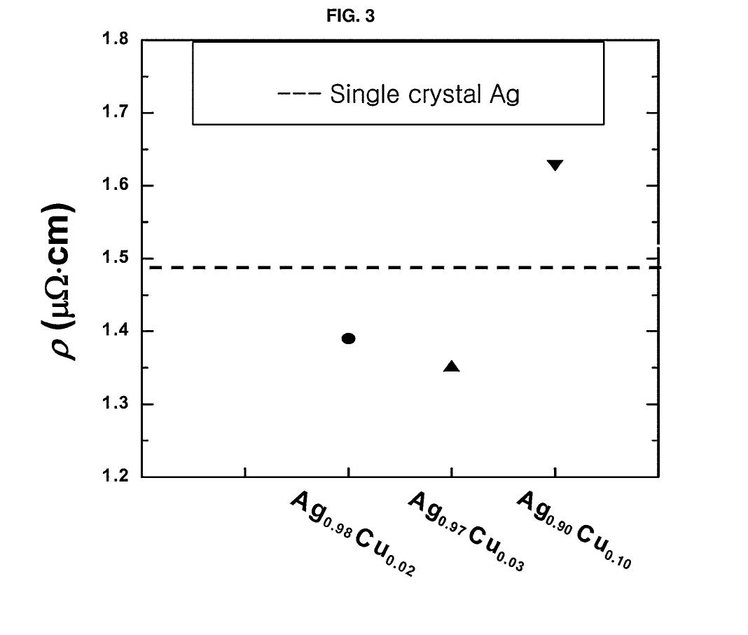

FIG. 1 shows electrical resistivity according to scattering between electrons and lattices. FIG. 2 shows an image of the metal single crystal formed in Example 2, together with diagrams for structurally analyzing the metal single crystal. FIG. 3 is a graph of the electrical resistivity of the metal single crystals in Examples and the Comparative Example of the following Example section.

Formed by growing an electrically superior metal doped with a hetero metal element as a mixed crystal, the metal single crystal with a hetero-metal atom substituted in accordance with the present invention, as can be seen, exhibits better electrical properties than the original metal and is improved in strength. A detailed description will be given of the theoretical background and embodiments of the metal single crystal with a hetero-metal atom substituted.

As a rule, the electrical resistivity of bulk metal is determined by various factors including the scattering of electrons by phonons, which are collective oscillations of the lattice of atoms, an atomic detect within a material, dislocation, and grain boundary scattering.

Inter alia, the scattering of electrons by lattice phonons makes a predominant contribution to the electrical resistivity of metal, which varies depending on temperature. In a metal, the lattice phonon, that is, the excitation, decreases with temperature, which leads to a reduction in the scattering of electrons by phonons and thus in the electrical resistivity. Conversely, an elevation in temperature increases phonons, resulting in an increase the scattering of electrons and thus the electrical resistivity.

The electrical conductivity caused by impurities is much smaller than that caused by electron-phonon scattering. Near room temperatures, the effect of impurities on electrical conductivity is negligible. At extremely low temperatures, the contribution of defects including impurities to electrical conductivity appears as these impurities scatter electrons.

The relationship between electrical resistivity and phonon-electron scattering is accounted for by the Bloch-Gruneisen formula of Equation 1.

$${ρ}_{el - ph} = {{α}_{el - ph} ( \frac{T}{{θ}_{R}} )}^{5} {\int }_{0}^{\frac{{θ}_{R}}{T}} \frac{{x}^{5}}{( {e}^{x} - 1 ) ( 1 - {e}^{- x} )} d x \qquad Equation 1$$

wherein

T=temperature,

θ_{R}=the Debye temperature constant of a given material

ρₑₗ₋ₚₕ=a constant defining electron-phonon scattering.

The equation is well coincident with the results of experiments for the dependence of electrical resistivity on electron-phonon scattering. In FIG. 1, measurements are marked with symbols, and lines are obtained by fitting the symbols to the equation.

In the principle of the present invention, the excitation of atoms or molecules in a material is suppressed as much as possible by impurity doping, which leads to reducing the contribution of electron-phonon scattering to electrical resistivity to as much of a degree as possible.

In the present invention, a small amount of impurities are doped into a metal single crystal to modulate the lattice oscillation in such a manner as to reduce electron scattering as much as possible, thereby correspondingly increasing electrical conductivity. The dopant is not a simple impurity causing electron scattering, but functions to modulate the periodic lattice oscillation to control electron-phonon scattering and thus electrical conductivity.

A better understanding of the present invention may be obtained through the following examples that are set forth to illustrate, but are not to be construed as limiting the present invention.

### EXAMPLE 1

Prepared was A_{1-X}B_{X} wherein A was silver, B was copper, and x was 0.01.

Copper and silver were weighed and introduced in a molar ratio of Ag_{0.99}Cu_{0.01} into a carbon crucible. A silver single crystal in a rectangular parallelopipedon form with (111) planes was suspended as a long seed through a Kanthal wire from a holder.

The crucible containing the two different metals was positioned to fit to the center of an induction coil within a chamber of a crystal growth chamber using the Czochralski process. Then, the prepared seed holder was immobilized to a rod at an upper portion within the chamber.

After the inlet thereof was closed with a locking screw, the chamber was vacuumed using a rotary pump. In this regard, after the chamber inlet is doubly closed with an additional clamp, the thermostat (KP-1000) of the generator was programmed such that the temperature of the chamber could be heated to the melting point of the material (approximately 930° C.).

Before the materials started to undergo oxidation, the chamber temperature was elevated up to approximately 150° C. over one hr and maintained at this temperature for an additional one hr during which high-purity argon gas was introduced into the chamber to a pressure 1.2-fold higher than the atmospheric temperature so as to prevent the materials from reacting with oxygen.

At this time, the operation of the rotary pump was stopped before the introduction of argon gas. Once the inside of the chamber was stabilized after the introduction of gas, the temperature was elevated to the melting point of the materials in the crucible according to the program. At this point, the chamber was maintained for 1-2 hrs so that molten copper and silver, which are different in specific gravity from each other, would be sufficiently mixed.

Subsequently, the seed mounted onto the upper portion of the chamber was slowly lowered immediately before contact to the surface of the molten mixture, and an arrangement with a temperature gradient along the length of the crucible was made for about 1 hr. Then, the seed was brought to the closest distance from the surface of the molten materials so that the surface tension could allow the molten materials to cling to the seed.

If the temperature of the contact was too high, it was likely to abruptly melt the seed. In this case, the above-mentioned procedure was repeated after the temperature was lowered to an appropriate point. After the solution stably clung to the seed for 30 min, the seed-mounted rod was rotated at a speed of 3 rpm for 30 min. Afterwards, the rotation was continued in order to grow the crystal into a homogeneous structure. To raise a crystal of quality, the seed was pull upward at a rate of 1 cm/hr while the temperature at the contact was maintained for about 1 hr.

After a neck long about 1 cm was constructed, the temperature was reduced so as to widen the diameter of the crystal. In an initial stage, the temperature was greatly decreased within a short time to make a shoulder of the crystal with the seed rising at a rate of 6 mm/hr. Until the diameter of the crystal reached 1.5 cm, the temperature drop was slowed down over a prolonged period of time with the seed rising rate reduced to 5 mm/hr. Once the crystal widened to a diameter of 1.5 cm, the seed rising rate was reduced down to 3 mm/hr while the temperature was maintained.

Under monitoring, the crystal was allowed to grow up to approximately 5 cm in length with its diameter maintained at a constant level. At this time, careful observation must be made to see whether the liquid surface was solidified or not.

After a sufficient length of the crystal was obtained, the temperature was slowly elevated to withdraw the crystal from the liquid surface. Care must be taken because a steep temperature elevation is highly apt to break the crystal, exerting a negative influence on the crystalline structure of the grown single crystal. The slow temperature elevation was conducted over approximately 1 hr after which the temperature elevation rate was slowly increased within a shorter time.

When the overall diameter of the crystal reached the neck diameter, the crystal was taken off. Through the above procedure, a mixed single crystal of Ag_{0.99}Cu_{0.01} was formed.

Details of the crystal growth device using the Czochralski process are omitted since it is generally known in the art.

### EXAMPLE 2

A mixed crystal of Ag_{0.98}Cu_{0.02} was grown as a single crystal. In this regard, copper and silver were weighed and introduced in such a molar ratio as in Ag_{0.98}Cu_{0.02} into a carbon crucible. A silver single crystal in a rectangular parallelopipedon form with (111) planes was suspended as a long seed through a Kanthal wire from a holder.

The other procedures were conducted in the same manner as in Example 1 to form a mixed crystal of Ag_{0.98}Cu_{0.02} as a metal single crystal.

### EXAMPLE 3

A mixed crystal of Ag_{0.97}Cu_{0.03} was grown as a single crystal. In this regard, copper and silver were weighed and introduced in such a molar ratio as in Ag_{0.97}Cu_{0.03} into a carbon crucible. A silver single crystal in a rectangular parallelopipedon form with (111) planes was suspended as a long seed through a Kanthal wire from a holder.

The other procedures were conducted in the same manner as in Example 1 to form a mixed crystal of Ag_{0.97}Cu_{0.03} as a metal single crystal.

### COMPARATIVE EXAMPLE

A mixed crystal of Ag_{0.90}Cu_{0.10} was grown as a single crystal. In this regard, copper and silver were weighed and introduced in a molar ratio of Ag_{0.90}Cu_{0.10} into a carbon crucible. A silver single crystal in a rectangular parallelopipedon form with (111) planes was suspended as a long seed through a Kanthal wire from a holder.

The other procedures were conducted in the same manner as in Example 1 to form a mixed crystal of Ag_{0.90}Cu_{0.10} as a metal single crystal.

Measurement was made of physical properties of the metal single crystals constructed above. FIG. 2 shows an image of the metal single crystal formed in Example 2, together with diagrams for structurally analyzing the metal single crystal. As can be seen, the single crystal was observed to consist of a neck, a body, and a tail. Likewise, the metal single crystals prepared in Examples 1 and 3 were also observed to have the same structure. In addition, the crystal of the Comparative Example grew into a similar form although its growth rate was poor.

Next, the metal single crystals prepared in the Examples and the Comparative Example were measured for electrical resistivity. For use in structural and electrical analysis, specimens were prepared from the metal single crystals by an electric discharge machining process, without distorting their crystalline structures.

Resistivity was measured using a four-probe method and a current-reversal method while a gold-coated pogo pin was employed to reduce the contact resistance of the sample and to make the contact surface uniform.

In order to reduce the additional voltage generation attributed to a thermoelectric effect, a voltage was repeatedly measured while a current was flowed across a specimen in opposite directions.

This method is intended to give a reliable result by eliminating a difference between two temperature measurements. For measurement consistency, all the specimens had the homogeneous dimensions of 3×0.5×30 mm³.

Measurements of electrical resistivity are depicted in FIG. 3. As can be seen, the mixed crystal of Example 3 was measured to have an electrical resistivity of 1.35 μΩ·cm, which was improved by 15% compared to 1.59 μΩ·cm, the resistivity of poly silver, and by 11%, compared to 1.52 μΩ·cm, the resistivity of single crystal silver.

Also, the mixed crystals of Examples 1 and 2 were lower in electrical resistivity than pure silver.

In contrast, the electrical resistivity of the mixed crystal prepared in the Comparative Example was higher than that of a copper single crystal or a silver single crystal. For Ag_{1-X}Cu_{X} wherein x exceeds 0.09, the mixed crystal was found to grow, but with difficulty in forming a single crystal, which resulted in increasing the electrical resistivity. When x is below 0.01, the copper component is too small in quantity to function as a dopant, making trivial contribution to a decrease in electrical resistivity.

Although the present invention has been explained with embodiments where silver is a main component with copper elements functioning as dopants, similar results can be obtained when copper is a main component with silver elements functioning as dopants. Therefore, it is obvious that the principle of the present invention can be applied to other metals. Also, it will be apparent to those skilled in the art that the present invention is not limited only to the embodiments described above, but can also be implemented with other electroconductive metal elements that fall within the scope of the present invention.

As described hitherto, the present invention pertains to a metal single crystal with a substituted hetero-metal atom. Growing as a single crystal, a mixed crystal of a metal doped with a hetero-metal element can exhibit better electrical properties than the base metal.

What is claimed is:

1. A metal single crystal with a substituted a hetero-metal atom, formed by doping metal element A with a hetero metal atom B to form an A_{1-X}B_{X} material wherein metal A is an element selected from among silver, copper, platinum, and gold, B is an element selected from among silver, copper, platinum and gold, the metal B being different from the metal A, and 0.01≦x≦0.09, and growing the material as a mixed crystal by means of a high temperature melting method.

2. The metal single crystal of claim 1, wherein the metal A is silver and the metal B is copper.

3. The methal single crystal of claim 1, wherein the high-temperature melting process is a Czochralski process.
